(19) United States
(12) Patent Application Publication
(10) Pub. No.: US 2008/0099902 A1
(43) Pub. Date: May 1, 2008

(54) Insertion-type semiconductor device and fabrication method thereof

(75) Inventors: Ming-Ke Shih, Taichung (TW); Ping-Yi Chu, Taichung (TW); Yong-Liang Chen, Taichung (TW); Chien-Chih Sung, Taichung (TW); Chung-Pao Wang, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/706,802

(22) Filed: Feb. 14, 2007

(30) Foreign Application Priority Data
Oct. 26, 2006 (TW) 095139487

(51) Int. Cl. H01L 23/02; H01L 21/00

(52) U.S. Cl. 257/679; 438/126; 257/E23.18; 257/E21.001

(57) ABSTRACT

The present invention provides an insertion-type semiconductor device and a fabrication method thereof, including the steps of: mounting a chip on a BGA substrate and performing a packaging molding process; providing an electrical connecting board formed with a plurality of electrical terminals thereon for allowing the packaged substrate to electrically connect with the electrical terminals on the electrical connecting board via a conductive element thereof; covering a lid to form an insertion-type semiconductor device. As size of the solder pads is much smaller than the electrical terminals of the insertion-type semiconductor device, the area under the semiconductor chip can be reduced to minimize the deformable area of the semiconductor chip when being pressed in the molding process, thereby preventing damage to the semiconductor chip and also meeting the specification requirement of an insertion-type semiconductor device.

### BACKGROUND OF THE INVENTION

1. Field of the Invention

The present invention relates generally to a semiconductor device and fabrication method thereof, and more particularly to an insertion-type semiconductor device and fabrication method thereof.

2. Description of Related Art

With development of the science and technology, insertion-type semiconductor devices such as security digital cards (SD cards) and multi-media cards (MMC) have become a new generation of multimedia storage devices, and have been widely applied in multimedia products such as digital cameras, digital videos, portable or desktop computers, mobile phones, personal stereos, electronic recorders and household electronics. The insertion-type semiconductor devices are erasable, light and small, which can save data without the need of power supply and have functions of anti-shake, anti-magnetism and anti-dust.

Generally, an insertion-type semiconductor device is a small IC device having a memory chip and a controller chip for storing and processing various kinds of data. A multi-chip stacking structure is often used in such an insertion-type semiconductor device, that is, the controller chip is stacked on the memory chip and meanwhile a chip carrier such as a substrate is used to support the stacking unit. Then, a packaging process is performed and a lid covers the packaged unit so as to form an insertion-type semiconductor device. Related technique is disclosed in U.S. Pat. No. 6,040,622 with a title of ‘Semiconductor package using terminals formed on a conductive layer of a circuit board’ and JP Patent No. 62-239554 with a title of ‘1C CARD TYPE EP-ROM STRUCTURE’.

FIGS. 1A and 1B are respectively planar and cross-sectional diagrams of an insertion-type semiconductor package applied in SD cards disclosed by Taiwan Patent No. M294711. As shown in FIGS. 1A and 1B, the insertion-type semiconductor package comprises a substrate 11 having a first surface 111 and a second surface 112 and a semiconductor chip 13 mounted on the substrate 11. A plurality of electrical terminals 12 is formed on the second surface 112 of the substrate 11 and exposed from the solder mask layer 15 encapsulating the surface of the substrate 11. To meet requirement for lighter, thinner, smaller and shorter electronic products, the semiconductor chip 13 is mounted on the first surface 111 of the substrate 11 corresponding to the electrical terminals 12 of the second surface 112 of the substrate and electrically connected with the electrical terminals 12 through vias (not shown) of the substrate 11 for saving spaces. However, as the substrate 11 is very thin and the electrical terminals 12 having a size of 0.9*2.9 mm are concavely disposed inside the solder mask layer 15, when a resin injection pressure is applied on the semiconductor chip 13 during the molding process, the semiconductor chip 13 disposed corresponding to the electrical terminals 12 will use edges of the solder mask layer 15 where the electrical terminals 12 are exposed as theorectical point of support S and exposed portion L of the electrical terminals 12 exposed from the solder mask layer 15 is a deformable area for the semiconductor chip 13. As a result, the semiconductor chip 13 can easily crack from the theorectical point of support S due to big injection pressure.

Therefore, how to overcome the cracking problem of the semiconductor chip disposed on the substrate corresponding to the electrical terminals in a molding process for small sized insertion-type semiconductor device has become urgent.

### SUMMARY OF THE INVENTION

According to the above drawbacks, an objective of the present invention is to provide an insertion-type semiconductor device and fabrication method thereof, through which cracking of the semiconductor chip disposed on the substrate corresponding to the electrical terminals of conventional insertion-type semiconductor devices can be overcome.

Another objective of the present invention is to provide an insertion-type semiconductor device and fabrication method thereof, which has improved packaging quality and can be applied in small sized insertion-type electronic devices.

In order to attain the above and other objectives, the present invention discloses an insertion-type semiconductor device, which comprises: a substrate having a first surface and a second surface opposite to the first surface, wherein a plurality of solder pads is formed on the second surface; a semiconductor chip mounted on and electrically connected with the first surface of the substrate; an encapsulant formed on the first surface of the substrate and encapsulating the semiconductor chip; an electrical connecting board having a plurality of electrical terminals disposed corresponding to the solder pads of the substrate such that the packaged substrate can be mounted on the electrical connecting board with the solder pads electrically connected to the electrical terminals through a conductive element; and a lid mounted on the electrical connecting board and covering the substrate, wherein the electrical terminals of the electrical connecting board are exposed from the lid.

The substrate is a BGA substrate and the solder pads of the substrate can be arranged in a straight line or staggeringly arranged corresponding to the electrical terminals of the electrical connecting board. Planar size of the solder pads is smaller than that of the electrical terminals. The solder pads of the substrate can be electrically connected with the electrical terminals of the electrical connecting board through conductive bumps such as solder balls or pre-solder bumps, or through metallic bumps protrudingly disposed on the electrical terminals of the electrical connecting board.

The present invention also discloses a fabrication method of the insertion-type semiconductor device, which comprises the steps of: providing a substrate having a first surface and a second surface opposite to the first surface, wherein, a plurality of solder pads is disposed on the second surface of the substrate and at least a semiconductor chip is mounted on and electrically connected with the first surface of the substrate, and forming an encapsulant encapsulating the semiconductor chip on the first surface of the substrate; mounting the packaged substrate on an electrical connecting board, wherein the electrical connecting board has a plurality of electrical terminals corresponding to the solder pads of the substrate such that the solder pads of the substrate can be electrically connected with the electrical terminals of the electrical connecting board through a conductive element; and disposing a lid on the electrical connecting board for covering the packaged substrate, the electrical terminals of the electrical connecting board being exposed from the lid.

The substrate is a BGA substrate and the solder pads of the substrate can be arranged in a straight line or staggeringly arranged corresponding to the electrical terminals of the electrical connecting board. Planar size of the solder pads is smaller than that of the electrical terminals. The solder pads of the substrate can be electrically connected with the electrical terminals of the electrical connecting board through conductive bumps such as solder balls or pre-solder bumps that are pre-mounted to the solder pads, or through metallic bumps protrudingly disposed on the electrical terminals of the electrical connecting board, thereby electrically connecting the semiconductor chip to the outside.

Therefore, the fabrication method of the insertion-type semiconductor device mainly comprises: mounting a semiconductor chip on such as a BGA substrate and performing a packaging molding process; mounting solder balls or pre-solder bumps on the solder pads of the substrate; providing an electrical connecting board having a plurality of electrical terminals such that the packaged substrate can be electrically connected with the electrical terminals of the electrical connecting board through the solder balls or pre-solder bumps, alternatively, the solder pads of the substrate can be electrically connected with the electrical terminals of the electrical connecting boards through metallic bumps pre-disposed on the electrical terminals. As outer diameter of the solder pads (about 0.3-0.6 mm, preferably 0.4 mm) is much smaller than size of the electrical terminals (0.9*2.9 mm), the suspension area under the semiconductor chip is reduced so as to minimize the deformable area of the semiconductor chip when being pressed in the molding process, thereby preventing cracking of the semiconductor chip. Thereafter, the packaged substrate can be disposed on an electrical connecting board having a plurality of electrical terminals such that the semiconductor chip can be electrically connected with an external device through the substrate and the electrical connecting board, which meanwhile meets the common specification of an insertion-type semiconductor device.

### BRIEF DESCRIPTION OF DRAWINGS

FIG. 1A is a planar diagram of a conventional insertion-type semiconductor device;

FIG. 1B is a sectional diagram of a conventional insertion-type semiconductor device;

FIGS. 2A to 2G are diagrams showing an insertion-type semiconductor device and fabrication method thereof according to a first embodiment of the present invention;

FIG. 2B′ is a diagram of a substrate according to another embodiment of the present invention; and

FIG. 3 is a diagram of an insertion-type semiconductor device according to a second embodiment of the present invention;

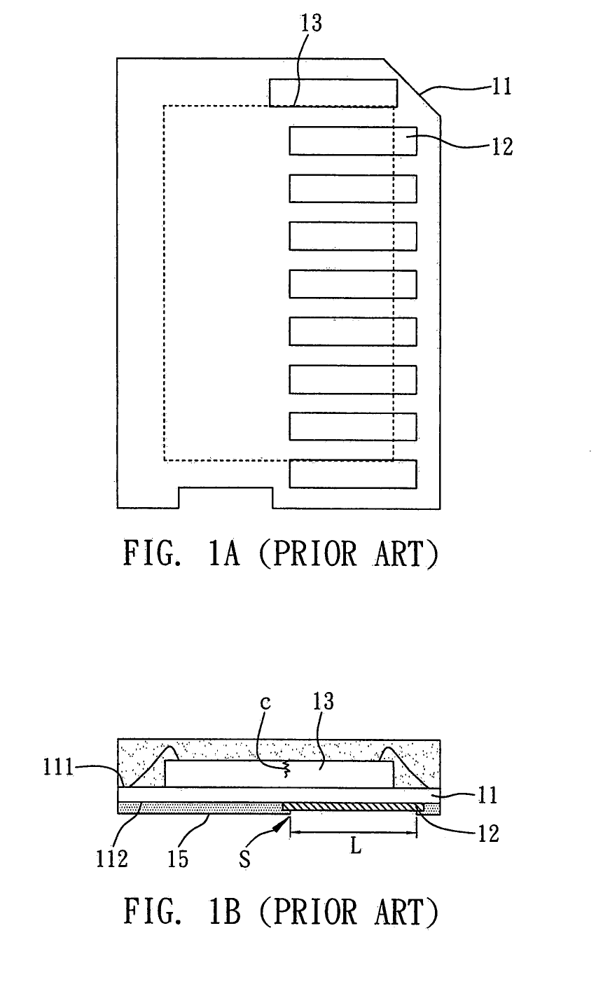

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

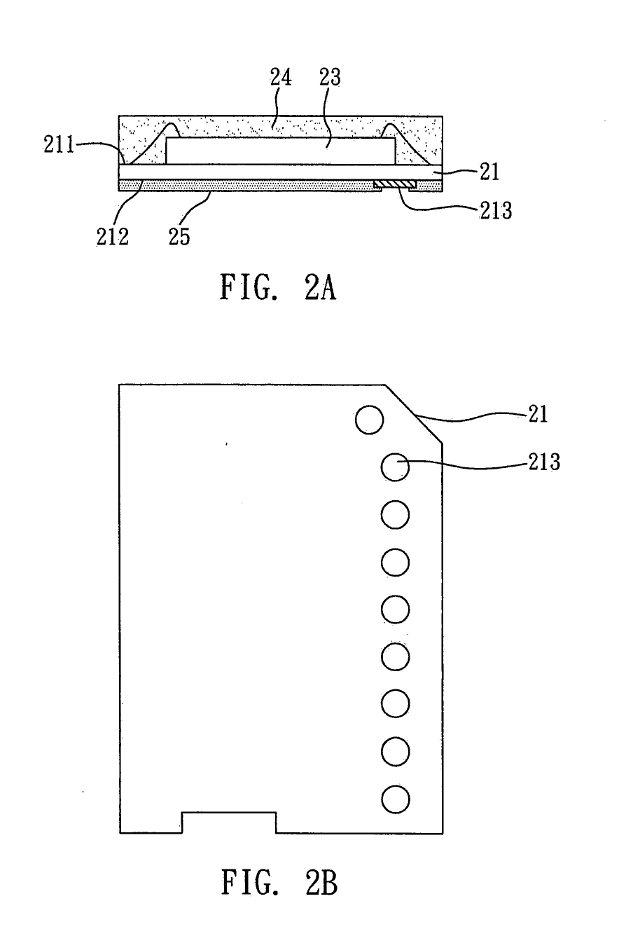

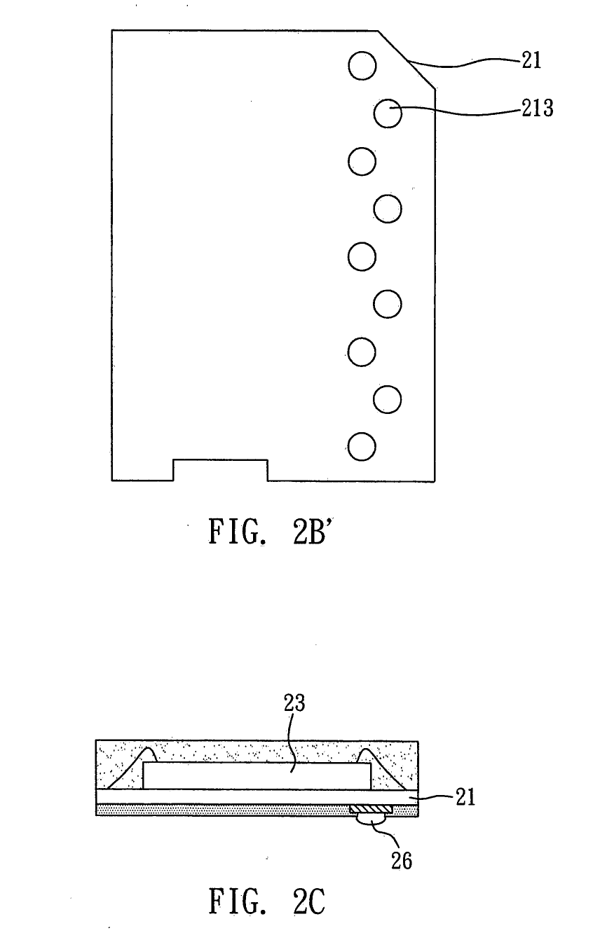

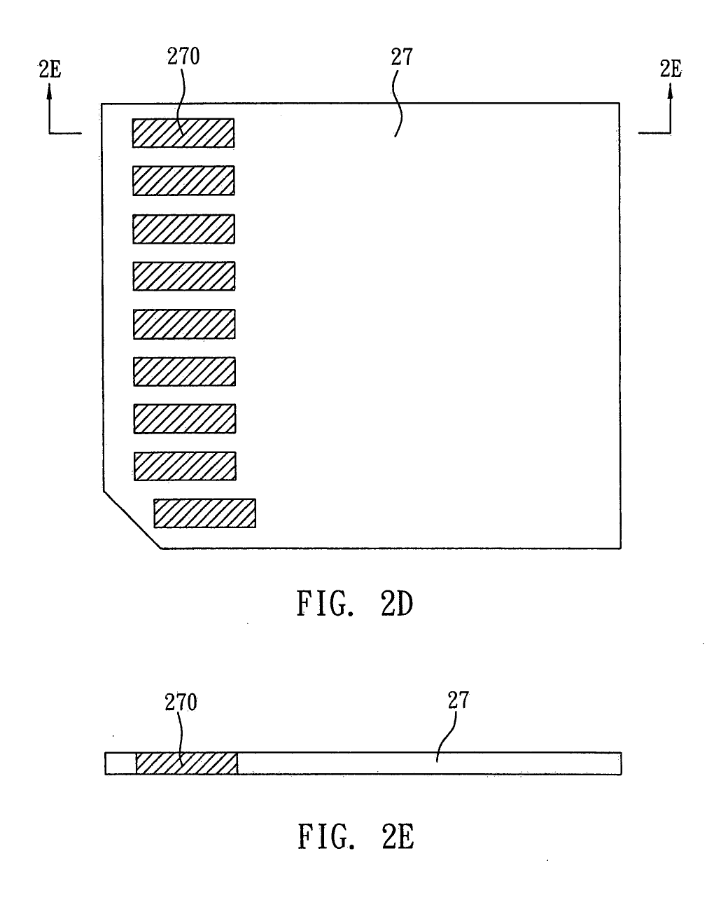

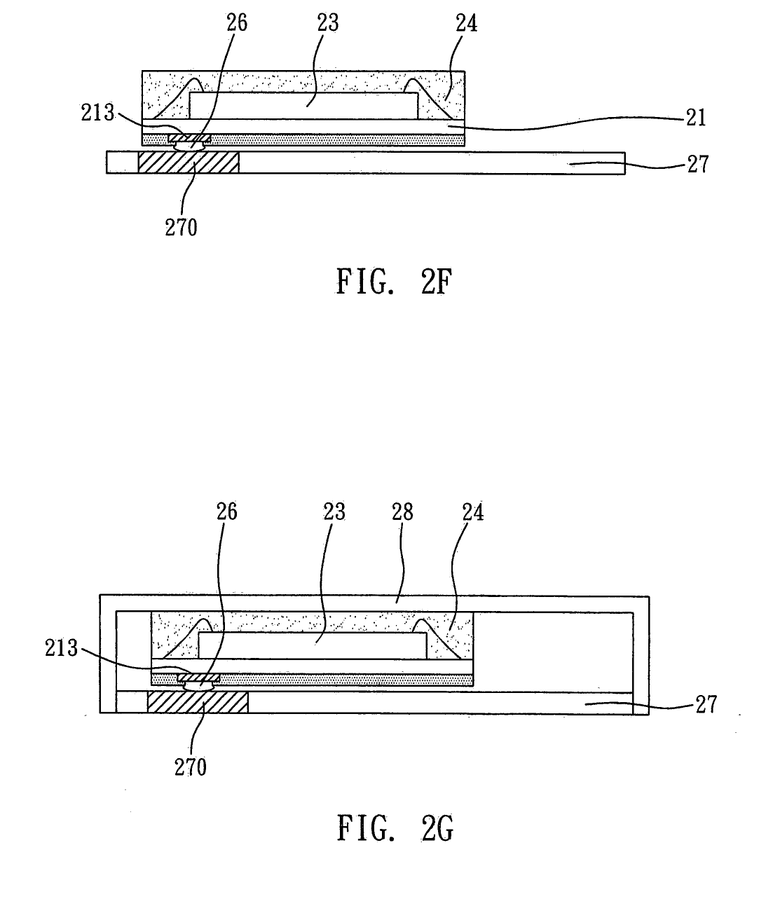

FIGS. 2A to 2G are diagrams showing an insertion-type semiconductor device and a fabrication method thereof. As shown in FIGS. 2A and 2B, a substrate 21 having a first surface 211 and a second surface 212 opposite to the first surface 211 is provided. A plurality of solder pads 213 is formed on the second surface 212 of the substrate 21. At least a semiconductor chip 23 is mounted to and electrically connected to the first surface 211 of the substrate 21 and an encapsulant 24 encapsulating the semiconductor chip 23 is formed on the first surface 211 of the substrate 21. Therein, the substrate 21 is a BGA substrate. The solder pads 213 are arranged in a straight line corresponding in position to electrical terminals of an insertion-type semiconductor device and outer diameter of the solder pads is about 0.3-0.6 mm, preferably 0.4 mm. A solder mask layer 25 is formed on the second surface 212 of the substrate 21 with the solder pads 213 exposed from the solder mask layer 25. In addition, to reduce the deformable area of the semiconductor chip 23 when the semiconductor chip 23 is pressed in the molding process, the solder pads 213 corresponding in position to the electrical terminals of the insertion-type semiconductor device can be staggeringly arranged, as shown in FIG. 2B′.

As shown in FIG. 2C, a plurality of conductive bumps 26 such as solder balls or pre-solder bumps is mounted on the solder pads 213 of the substrate 21.

As shown in FIGS. 2D and 2E, an electrical connecting board 27 is provided, size of which is same as a SD card. The electrical connecting board 27 has a first surface and a second surface opposite to the first surface, and is mainly made of a plastic material or a resin material such as FR4. Electrical terminals 270 are disposed inside the electrical connecting board 27, penetrating through the first and second surfaces of the electrical connecting board 27. The number and position of the electrical terminals 270 correspond to the number and position of the solder pads 213 of the substrate 21, and outer diameter of the solder pads 213, which is for example 0.4 mm, is much smaller than size of the electrical terminals 270, which is for example 0.9*2.9 mm.

In addition, appearance size of the electrical connecting board 27 and the number and size of the electrical terminals 270 meet specification requirement of SD insertion-type electronic device.

As shown in FIG. 2F, the packaged substrate 21 is mounted on the electrical connecting board 27 with the conductive bumps 26 on the solder pads 213 electrically connected to the electrical terminals 270 of the electrical connecting board 27.

As shown in FIG. 2G, a lid 28 is mounted on the electrical connecting board 27 for covering the substrate 21, wherein the electrical terminals 270 of the electrical connecting board 27 are exposed from the lid 28, thus forming an insertion-type semiconductor device of the present invention. Therein, the electrical terminals 270 are I/O terminals of the insertion-type semiconductor device for electrically connecting with an external device.

Through the above-described fabrication method, the present invention also discloses an insertion-type semiconductor device, which comprises: a substrate 21 having a first surface 211 and a second surface 212 opposite to the first surface 211, wherein a plurality of solder pads 213 is formed on the second surface 212; a semiconductor chip 23 mounted on and electrically connected with the first surface 211 of the substrate 21; an encapsulant 24 formed on the first surface 211 of the substrate 21 and encapsulating the semiconductor chip 23; an electrical connecting board 27 having a plurality of electrical terminals 270 disposed corresponding to the solder pads 213 of the substrate 21 such that the packaged substrate 21 can be mounted on the electrical connecting board 27 with the solder pads 213 electrically connected to the electrical terminals 270 through a conductive element; and a lid 28 mounted on the electrical connecting board 27 and covering the substrate 31, wherein the electrical terminals 270 of the electrical connecting board 27 are exposed from the lid 28.

The substrate 21 is a BGA substrate, and the solder pads 213 of the substrate 21 are arranged in a straight line or staggeringly arranged corresponding to the electrical terminals 270 of the electrical connecting board 27. Planar size of the solder pads 213 is smaller than that of the electrical terminals 270 for preventing the semiconductor chip 23 from cracking caused by molding pressure applied on the semiconductor chip 23. The conductive element can be conductive bumps 26 such as solder balls or pre-solder bumps disposed on the solder pads 213 of the substrate 21.

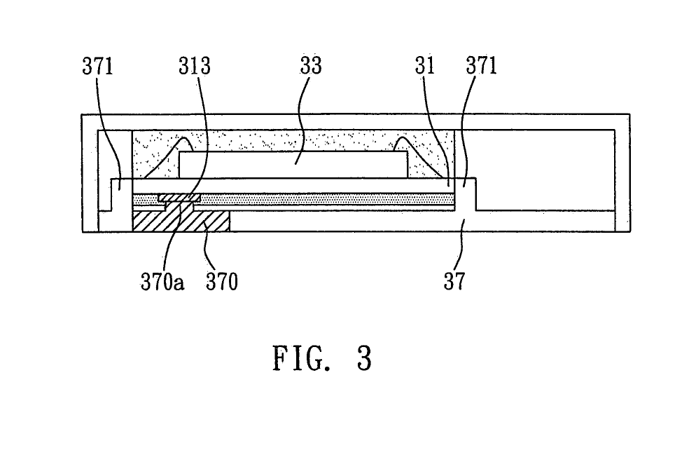

FIG. 3 is a diagram of an insertion-type semiconductor device according to a second embodiment of the present invention. The insertion-type semiconductor device is similar to that of the first embodiment. The main difference of the present embodiment from the first embodiment is the electrical terminals 370 of the substrate 31 have metallic bumps 370a protrudingly disposed thereon corresponding in position to the solder pads of the substrate 31 such that the substrate 31 can be contacted with the metallic bumps 370a through the solder pads 313 and thus electrically connected with the electrical terminals 370 of the electrical connecting board 37 for further external electrical connection.

Further, a fastening unit 371 can be disposed on the electrical connecting board 37 for efficiently fastening the packaged unit on the electrical connecting board 37.

Therefore, the fabrication method of the insertion-type semiconductor device mainly comprises: mounting a semiconductor chip on such as a BGA substrate and performing a packaging molding process; mounting solder balls or pre-solder bumps on the solder pads of the substrate; providing an electrical connecting board having a plurality of electrical terminals such that the packaged substrate can be electrically connected with the electrical terminals of the electrical connecting board through the solder balls or pre-solder bumps, alternatively, the solder pads of the substrate can be electrically connected with the electrical terminals of the electrical connecting boards through metallic bumps pre-disposed on the electrical terminals. As outer diameter of the solder pads (about 0.3-0.6 mm, preferably 0.4 mm) is much smaller than size of the electrical terminals (0.9*2.9 mm) of the insertion-type semiconductor device, the area under the semiconductor chip can be reduced to minimize the deformable area of the semiconductor chip when being pressed in the molding process, thereby preventing cracking of the semiconductor chip. Thereafter, the packaged substrate can be disposed on an electrical connecting board having a plurality of electrical terminals such that the semiconductor chip can be electrically connected with an external device through the substrate and the electrical connecting board, which meanwhile meets the common specification of an insertion-type semiconductor device.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. An insertion-type semiconductor device, comprising:
a substrate having a first surface and a second surface opposite to the first surface, wherein a plurality of solder pads is formed on the second surface;
a semiconductor chip mounted on and electrically connected with the first surface of the substrate;
an encapsulant formed on the first surface of the substrate and encapsulating the semiconductor chip;
an electrical connecting board having a plurality of electrical terminals disposed corresponding to the solder pads of the substrate such that the packaged substrate can be mounted on the electrical connecting board with the solder pads electrically connected to the electrical terminals through a conductive element; and
a lid mounted on the electrical connecting board and covering the substrate, wherein the electrical terminals of the electrical connecting board are exposed from the lid.

2. The insertion-type semiconductor device of claim 1, wherein the substrate is a BGA substrate.

3. The insertion-type semiconductor device of claim 1, wherein the solder pads of the substrate are arranged in a straight line corresponding in position to the electrical terminals.

4. The insertion-type semiconductor device of claim 1, wherein the solder pads are staggeringly arranged corresponding in position to the electrical terminals.

5. The insertion-type semiconductor device of claim 1, wherein the conductive element is selected from the group consisting of conductive bumps mounted on the solder pads and metallic bumps protrudingly disposed on the electrical connecting board.

6. The insertion-type semiconductor device of claim 5, wherein each of the conductive bumps is one of the group consisting of a solder ball and a pre-solder bump.

7. The insertion-type semiconductor device of claim 1, wherein the electrical connecting board is made of one of a plastic material and a resin material.

8. The insertion-type semiconductor device of claim 1, wherein the number and position of the electrical terminals correspond to the number and position of the solder pads of the substrate, and size of the solder pads is smaller than that of the electrical terminals.

9. The insertion-type semiconductor device of claim 1, wherein a fastening unit is disposed on the electrical connecting board for fastening the packaged substrate on the electrical connecting board.

10. The insertion-type semiconductor device of claim 1, wherein appearance size of the electrical connecting board and the number and size of the electrical terminals meet the specification requirement of the insertion-type semiconductor device.

11. A fabrication method an insertion-type semiconductor device, comprising the steps of:
providing a substrate having a first surface and a second surface opposite to the first surface, wherein, a plurality of solder pads is disposed on the second surface of the substrate and at least a semiconductor chip is mounted on and electrically connected with the first surface of the substrate, and forming an encapsulant encapsulating the semiconductor chip on the first surface of the substrate;
mounting the packaged substrate on an electrical connecting board, wherein the electrical connecting board has a plurality of electrical terminals corresponding to the solder pads of the substrate such that the solder pads of the substrate can be electrically connected with the electrical terminals of the electrical connecting board through a conductive element; and
disposing a lid on the electrical connecting board for covering the packaged substrate, the electrical terminals of the electrical connecting board being exposed from the lid.

12. The fabrication method of claim 11, wherein the substrate is a BGA substrate.

13. The fabrication method of claim 11, wherein the solder pads of the substrate are arranged in a straight line corresponding in position to the electrical terminals.

14. The fabrication method of claim 11, wherein the solder pads are staggeringly arranged corresponding in position to the electrical terminals.

15. The fabrication method of claim 11, wherein the conductive element is selected from the group consisting of conductive bumps mounted on the solder pads and metallic bumps protrudingly disposed on the electrical connecting board.

16. The fabrication method of claim 15, wherein each of the conductive bumps is one of the group consisting of a solder ball and a pre-solder bump.

17. The fabrication method of claim 11, wherein the electrical connecting board is made of one of a plastic material and a resin material.

18. The fabrication method of claim 11, wherein the number and position of the electrical terminals correspond to the number and position of the solder pads of the substrate, and size of the solder pads is smaller than that of the electrical terminals.

19. The fabrication method of claim 11, wherein a fastening unit is disposed on the electrical connecting board for fastening the packaged substrate on the electrical connecting board.

20. The fabrication method of claim 11, wherein appearance size of the electrical connecting board and the number and size of the electrical terminals meet the specification requirement of the insertion-type semiconductor device.
